(19) United States
(12) Patent Application Publication
(10) Pub. No.: US 2016/0056059 A1
(43) Pub. Date: Feb. 25, 2016

(54) COMPONENT FOR SEMICONDUCTOR PROCESS CHAMBER HAVING SURFACE TREATMENT TO REDUCE PARTICLE EMISSION

(71) Applicant: Applied Materials, Inc., Santa Clara, CA (US)

(72) Inventors: Jennifer SUN, Mountain View, CA (US); Biraja KANUNGO, San Jose, CA (US); Sunil SRINIVASAN, Milpitas, CA (US); Jinhan CHOI, San Ramon, CA (US); Anisul H. KHAN, Santa Clara, CA (US)

(73) Assignee: Applied Materials, Inc., Santa Clara, CA (US)

(21) Appl. No.: 14/832,671

(22) Filed: Aug. 21, 2015

Related U.S. Application Data
(60) Provisional application No. 62/040,865, filed on Aug. 22, 2014.

(51) Int. Cl. H01L 21/67; F27D 7/06; F27D 21/00; B28B 11/08

(52) U.S. Cl. CPC H01L 21/67011; B28B 11/0872; F27D 7/06; F27D 21/0014

(57) ABSTRACT

Examples of the disclosure generally relate to a component for use in a semiconductor process chamber includes a body having machined surfaces including a first surface and a second surface. The first surface is configured to interface with a support member of the semiconductor process chamber. The second surface is configured to face a processing region of the semiconductor process chamber. A treated area of the second surface includes relatively flatter peaks than an untreated area of the machined surfaces and exhibits an average roughness between 1 and 30 micro-inches.

This application claims benefit of U.S. provisional patent application Ser. No. 62/040,865, filed Aug. 22, 2014, which is hereby incorporated herein by reference.

### BACKGROUND

1. Field of the Disclosure

Embodiments of the present disclosure generally relate to a component for a semiconductor process chamber. More specifically, the disclosure relates to a component for a semiconductor process chamber having a surface treatment to reduce particle emission.

2. Description of the Related Art

In the manufacture of integrated circuits, semiconductor substrates undergo various processes within a semiconductor process chamber, such as deposition, etching, annealing, and the like. The semiconductor process chamber includes various components, some of which define a processing region within the chamber with respect to the substrate. For example, a semiconductor process chamber can include components, such as rings, shields, liners, and the like. Many semiconductor substrates are processed in the presence of a processing gas or gases that form a plasma within the processing region. Over time, the plasma consumes components in the chamber having surfaces exposed to the plasma. Moreover, the exposed surfaces of some components can generate particles, which can contaminate the semiconductor substrate being processed and increase defect rates.

### SUMMARY

In one example implementation, a component for use in a semiconductor process chamber includes a body having machined surfaces including a first surface and a second surface. The first surface is configured to interface with a support member of the semiconductor process chamber. The second surface is configured to face a processing region of the semiconductor process chamber. A treated area of the second surface includes relatively flatter peaks than an untreated area of the machined surfaces and exhibits an average roughness between 1 and 30 micro-inches.

In another example implementation, a method of fabricating a component for use in a semiconductor process chamber includes steps of: forming a body having machined surfaces, the machined surfaces including a first surface to interface a support member of the semiconductor process chamber and a second surface to interface a processing region of the semiconductor process chamber; configuring an area of the second surface for thermal sublimation treatment; and exposing the area of the second surface to a temperature above a sublimation temperature of a material of the second surface to form a treated area of the second surface having relatively flatter peaks than prior the thermal sublimation treatment.

In another example implementation, a method of fabricating a component for use in a semiconductor process chamber includes steps of: forming a body having machined surfaces, the machined surfaces including a first surface to interface a support member of the semiconductor process chamber and a second surface to interface a processing region of the semiconductor process chamber; configuring an area of the second surface for treatment; oxidizing the second surface within the area to form an oxidized layer of the second surface; and etching the oxidized layer to provide a treated area of the second surface having relative flatter peaks than prior the treatment.

### BRIEF DESCRIPTION OF THE DRAWINGS

So that the manner in which the above recited features of the present disclosure can be understood in detail, a more particular description of the invention, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a schematic, cross-sectional view of a semiconductor substrate process system according to one embodiment of the disclosure.

FIG. 2 is a cross-sectional side view of a ring assembly according to an embodiment.

FIG. 3 is a cross-sectional side view of a ring assembly according to another embodiment.

FIG. 4 is a flow diagram depicting a method of fabricating a component for use in a semiconductor process chamber according to an embodiment.

FIG. 5A shows a scanning electron microscope (SEM) image of a component surface without treatment;

FIGS. 5B-C show SEM images of a component surface after treatment.

FIG. 6 is a flow diagram depicting a method of fabricating a component for use in a semiconductor process chamber according to another embodiment.

FIG. 7A shows a schematic cross-section of the upper surface portion of a ring assembly prior to the surface treatment.

FIG. 7B shows a schematic cross-section of the upper surface portion of a ring assembly after surface treatment and prior to use in the process chamber.

To facilitate understanding, identical reference numerals have been used, where possible, to designate identical elements that are common to the figures. It is also contemplated that elements and features of one embodiment may be beneficially incorporated on other embodiments without further recitation.

### DETAILED DESCRIPTION

Embodiments of the disclosure generally provide a component for using in a semiconductor process chamber having a surface treatment to reduce particle emission in the presence of processing gas. In an example implementation, a component includes a body having machined surfaces, including a first surface configured to interface with a support member of the semiconductor process chamber, and a second surface configured to face a processing region of the chamber. The second surface can be exposed to plasma in the processing region and hence may be referred to herein as a “plasma facing surface.” During manufacture, the machined surfaces of the component can have a fractured and jagged morphology. If left untreated, the component surface can emit particles as the surface interfaces with a plasma and contaminate the substrate.

In various examples described herein, an area of the plasma facing surface of the component is treated to enhance surface morphology to reduce particle emission in the presence of processing gas, such as a plasma. The treated area of the plasma facing surface exhibits a less fractured and/or jagged surface morphology (e.g., flatter peaks) than the post-machined, untreated surface (e.g., sharper peaks), which reduces particle emission and contamination of the substrate. Various techniques are described herein for improving surface morphology of the plasma facing surface to reduce particle emission in the presence of processing gas.

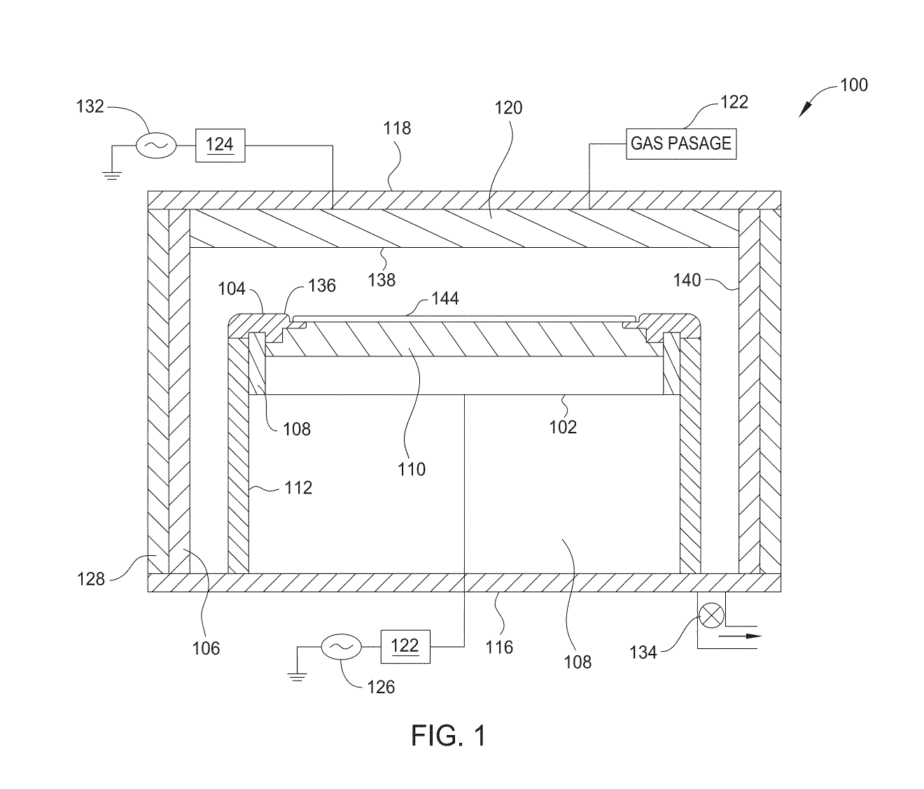

FIG. 1 is a schematic, cross sectional view of a semiconductor substrate process system according to one embodiment of the disclosure. The illustrated process system generally comprises a plasma chamber suitable for etching, chemical vapor deposition (CVD), and the like. The process system includes a process chamber 100 enclosed by a cylindrical side wall 128, a circular bottom wall 116, and a top wall or lid 118. The process chamber 100 may be utilized alone or as a processing module of an integrated semiconductor substrate processing system or cluster tool. A substrate support 108 is disposed in the process chamber 100 configured to support a semiconductor wafer or workpiece 144. The substrate support 108 is disposed below an anode electrode 120 mounted to the bottom of the lid 118. The anode electrode 120 may be perforated to function as a gas inlet through which process gases enter the process chamber 100 (e.g., the anode electrode 120 may be a showerhead) from a gas source 122.

The substrate support 108 may be biased by a DC power supply (now shown). A radio frequency (RF) power source 126 can be optionally coupled to the substrate support 108 through a matching network 122. The anode 120 can be coupled to an RF power source 132 through a matching network 124. The interior of the process chamber 100 is a high vacuum vessel that is coupled through a throttle valve (not shown) to a vacuum pump 134.

During processing, the semiconductor wafer 144 is placed on the substrate support 108 and the interior of the process chamber 100 is pumped down to a near vacuum environment. One or more processing gases is/are supplied through the anode electrode 120 (e.g., showerhead) into a processing region 114. The processing gas or gases is/are ignited into a plasma by applying power from the RF power source 132 to the anode electrode 120 and/or the RF power source 122 to the substrate support 108 while applying power from a bias source (not shown) to bias the substrate support 108. The formed plasma may be used to etch feature(s) in the semiconductor wafer 144 during processing and then pumped out of the process chamber 100 through the vacuum pump 134. It is to be understood that other components of the process chamber 100 have been omitted for purposes of clarity by example.

During processing, the plasma may extend not only to the semiconductor wafer 144, but also to the chamber walls. To protect the chamber walls from the plasma, the process chamber 100 can include a liner 106. The liner 106 can be removable in order to be cleaned and/or replaced.

The substrate support 100 generally includes a cathode 102, a ring assembly 104, a dielectric shield 108, and a support insulator 112. The cathode 102 can include an electrostatic chuck (ESC) 110 disposed thereon. The ESC 110 clamps the semiconductor substrate 144 against the cathode 102. Alternatively, a mechanical chuck (not shown) can be used to clamp the semiconductor substrate 144 against the cathode 102. The cathode 102 can be biased by a DC power source (not shown) and optionally the RF power source 126.

To maximize the concentration of reactive species and charged particles at the surface of the semiconductor wafer 144, RF current flow between the plasma and the cathode 102 should be concentrated in the area occupied by the semiconductor wafer 144. Thus, surfaces of the cathode 102 that are not covered by the semiconductor wafer 144 are covered by dielectric material, including the ring assembly 104 and the dielectric shield 108. The dielectric shield 108 comprises a cylinder of dielectric material that covers a side surface of the cathode 102. The ring assembly 104 rests on and overlaps a portion of the top surface of the cathode 102 that is outside of the perimeter of the semiconductor wafer 144. The substrate insulator 112 functions to electrical isolate the substrate support 108 from the chamber walls.

In general, the process chamber 100 includes one or more components that are exposed to plasma during processing. Each component generally includes a body having machined surfaces, including a first surface interfacing with a support member in the process chamber 100, and a second surface facing the process region 114 (“plasma facing surface”). Such components generally include shields, liners, showerheads, and the like. For example, the ring assembly 104 comprises a shield that has a surface interfacing with the substrate support 108 and a plasma facing surface 136 exposed to the processing region 114. The showerhead 120 includes a surface interfacing with the lid 118 and a plasma facing surface 138 exposed to the processing region 114. The liner 106 includes a surface interfacing with the wall 128 and a plasma facing surface 140 exposed to the processing region 114.

During processing, such components can emit particles from the surfaces exposed to the plasma, which can contaminate the semiconductor substrate 144. If left untreated, the machined surfaces of such components have peaks that can be characterized as jagged, fractured, and/or sharp. The tips of such peaks are more apt to break off during processing, causing the emission of particles from the components and contamination of the semiconductor wafer 144. Accordingly, the plasma facing surface of one or more of such components can have a treated area to enhance surface morphology to reduce particle emission in the presence of the plasma. The treated area of the plasma facing surface exhibits peaks that can be characterized as less jagged, less fractured, and/or less sharp (generally referred to as “flatter peaks”) than the post-machined, untreated surface. The tips of the flatter peaks are less apt to break off during processing of the semiconductor wafer 144. Thus, the treated area emits fewer particles during processing, reducing contamination of the semiconductor wafer 144.

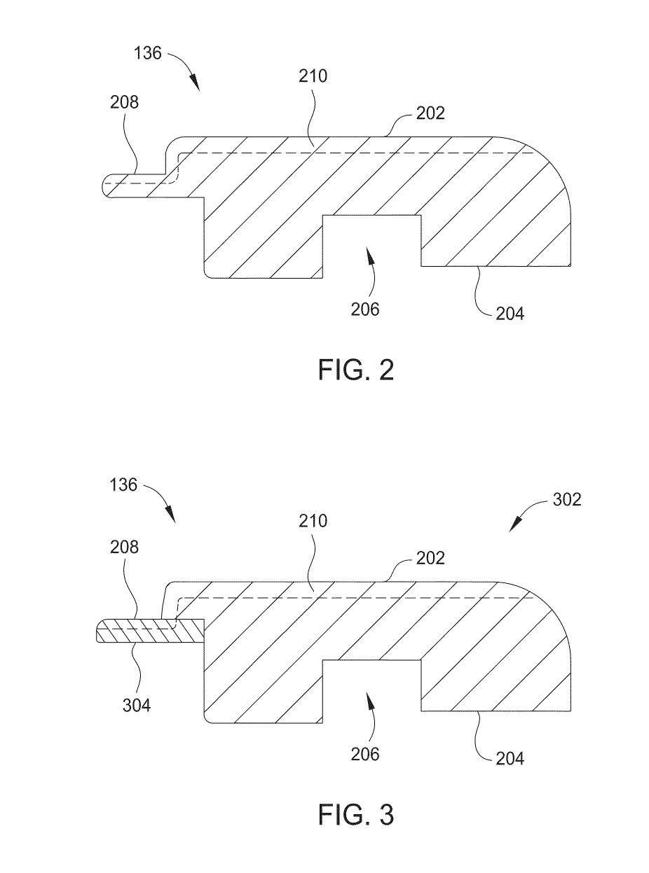

FIG. 2 is a cross-sectional side view of the ring assembly 104 according to an embodiment. The ring assembly 104 comprises a single-piece having an upper surface 202 and a lower surface 204. The upper surface 202 generally provides the plasma facing surface 136 of the ring assembly 104. The lower surface 204 generally includes a seating area 206 configured to interface with the dielectric shield 108. The upper surface 202 includes a seating area 208 interfacing with the semiconductor wafer 144. In an embodiment, the seating area 208 is substantially level with the semiconductor wafer 144. Alternatively, the semiconductor wafer 144 can rest on at least a portion of the seating area 208. The ring assembly 104 includes a treated area 210 of the upper surface 202. The treated area 210 can comprise all or a portion of the upper surface 202. In an embodiment, the treated area 210 comprises at least the portion of the upper surface 202 most proximate to the semiconductor wafer 144, including the seating area 208. The ring assembly 104 is formed of a dielectric material, such as quartz, silicon carbide, or the like. In an embodiment, the ring assembly 104 can comprise a first dielectric material, and all or a portion of the upper surface 206 can be coated with a second dielectric material. For example, the ring assembly 104 can generally comprise quartz, and at least the seating area 208 can be coated with silicon carbide.

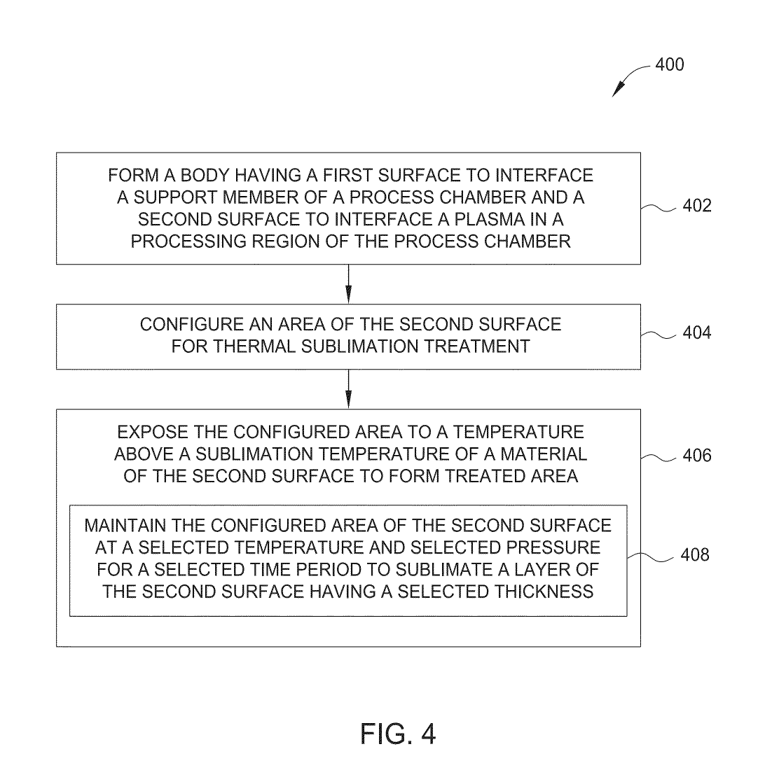

FIG. 3 is a cross-sectional side view of the ring assembly 104 according to another embodiment. In the present embodiment, the ring assembly 104 generally comprises two pieces: a ring 302 and a ring insert 304. The ring 302 includes the lower surface 204 and the seating area 206. The ring 302 and the ring insert 304 cooperate to form the upper surface 202 including the seating area 208. The seating area 208 is substantially formed by the ring insert 304. As noted above, the treated area 210 can comprise all or a portion of the upper surface 202. The treated area 210 is formed prior to use in the process chamber 100. In an embodiment, the treated area 210 comprises at least the portion of the upper surface 202 most proximate to the semiconductor wafer 144, including the seating area 208 (e.g., the ring insert 304). The ring 302 and the ring insert 304 are formed of a dielectric material, such as quartz, silicon carbide, or the like. In an embodiment, the ring assembly 302 can comprise a first dielectric material, and the ring insert 304 can comprise a second dielectric material. For example, the ring 302 can generally comprise quartz, and the ring insert 304 can comprise silicon carbide.

Referring to FIGS. 2 and 3, in general, the treated area 210 of the ring assembly 104, prior to use in the process chamber 100, exhibits a surface morphology having flatter peaks than untreated area of the ring assembly 104 (e.g., the lower surface 204 and/or untreated area of the upper surface 202). In one embodiment, the treated area 210 can have an average roughness between 1 and 30 micro-inches (μ-in). In an embodiment, the treated area includes an oxidized and etched area of the upper surface 202. In another embodiment, the treated area includes a layer remaining after thermal sublimation of another layer of the upper surface 202.

FIGS. 2 and 3 show one example of a component having a plasma facing surface that can be treated as described herein. It is to be understood that other components, including a showerhead, a liner, other shields, and the like having plasma facing surfaces can be treated in similar fashion.

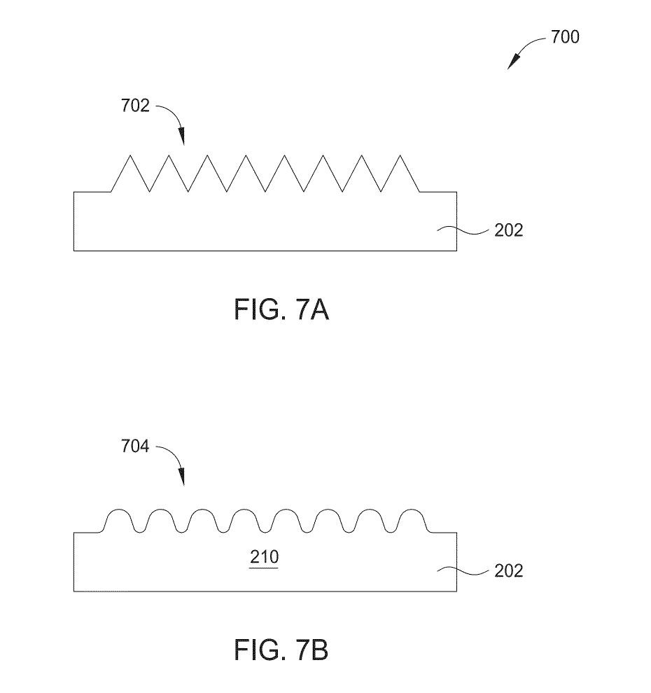

FIG. 7A shows a schematic cross-section of the upper surface 202 portion of the ring assembly 104 prior to the surface treatment. As schematically shown, the upper surface 202 is a machined surface having sharp surface projections 702 on a micro-scale. Thus, the machined surface has a fractured and jagged morphology. The sharp surface projections 702 comprise the material of the upper surface 202 (e.g., silicon carbide).

FIG. 7B shows a schematic cross-section of the upper surface 202 portion of the ring assembly 104 after surface treatment and prior to use in the process chamber 100. As schematically shown, the upper surface 202 includes a treated area 210 that comprises a non-machined surface having rounded surface projections 704 on a micro-scale. The non-machined surface of the treated area 210 exhibits a less fractured and/or jagged surface morphology (e.g., flatter surface projections 704) than the machined, untreated surface, which reduces particle emission and contamination of the substrate. The rounded surface projections 704 comprise the material of the upper surface 202, and can include other material(s) resulting from the surface treatment process. For example, in an embodiment described below, the surface treatment process includes steps of oxidation and etching. The treated area 210 can include residual etchant material, for example, bonded to the rounded surface projections 704.

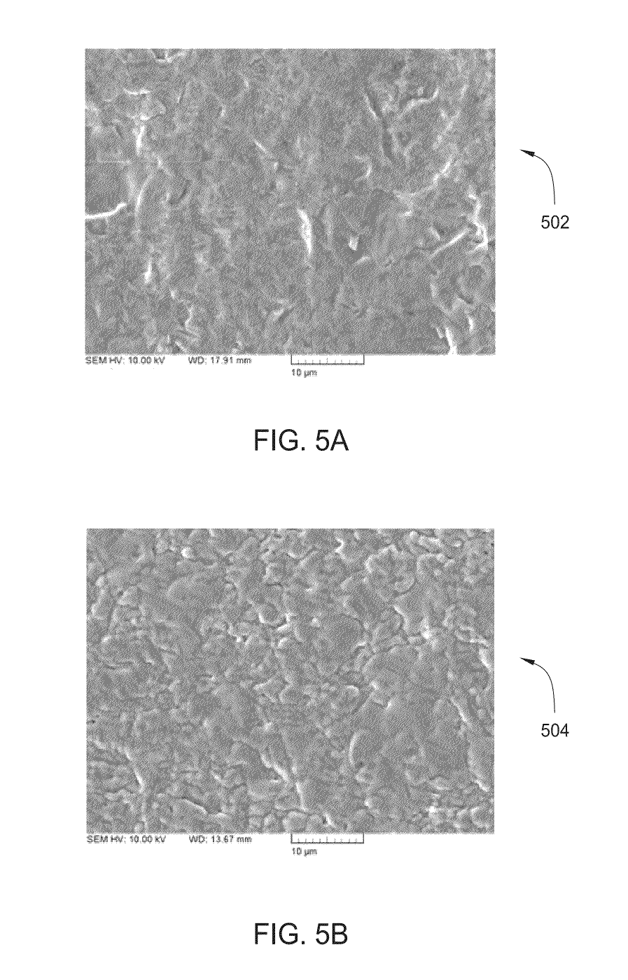

FIG. 4 is a flow diagram depicting a method 400 of fabricating a component for use in a semiconductor process chamber according to an embodiment. The method 400 is completed prior to initial first use and installation of the component in the process chamber 100. The method 400 begins at step 402, where a body is formed having a first surface to interface a support member of the process chamber and a second surface to interface a plasma in a processing region of the process chamber. At step 404, an area of the second surface is configured for thermal sublimation treatment. For example, one or more masks can be used to expose the area of the second surface for thermal sublimation treatment, while shielding other areas of the component from the thermal sublimation treatment. At step 406, the configured area is exposed to a temperature above a sublimation temperature of a material of the second surface to form a treated area. The step 406 can include a step 408. In step 408, the configured area of the second surface is maintained at a selected temperature and selected pressure for a selected time period to sublimate a layer of the second surface having a selected thickness. In an embodiment, the selected temperature is between 1600 and 2300 degrees Celsius (° C.), the selected pressure is between 10⁻³ and 10⁻⁷ standard atmosphere (atm), and the time period is between 2 and 10 hours. Such temperature, pressure, and time parameters can be used when the treated area 210 includes quartz, silicon carbide, or a combination of such materials. Using such temperature, pressure, and time parameters in a treated area comprising quartz, silicon carbide, or a combination thereof can result in sublimation of a layer having a selected thickness between 20 and 50 μpm. After completion of the method 400, the component is ready for cleaning and subsequent use in the process chamber 100.

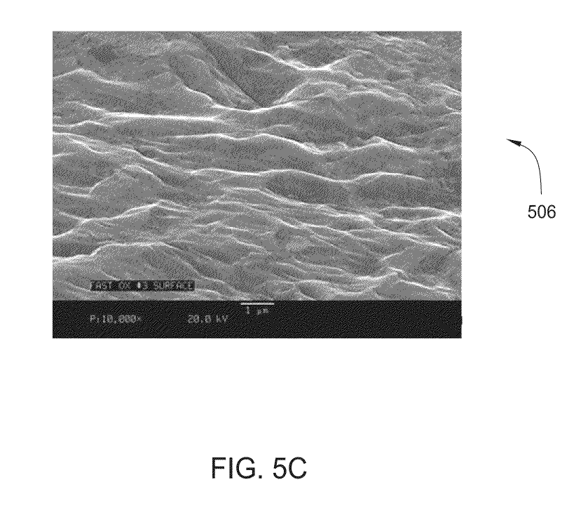

FIG. 5A shows a scanning electron microscope (SEM) image 502 of an untreated surface of a component comprising silicon carbide prior to use in the process chamber 100. The untreated surface includes jagged, fractured, and/or sharp peaks. FIG. 5B shows a SEM image 504 of a thermal sublimation treated surface of a component comprising silicon carbide. As shown, the treated surface includes less jagged, fractured, and/or sharp peaks than the untreated surface shown in FIG. 5A (e.g., generally flatter peaks). Components comprising other materials, such as quartz, exhibit similar surface morphology after thermal sublimation treatment.

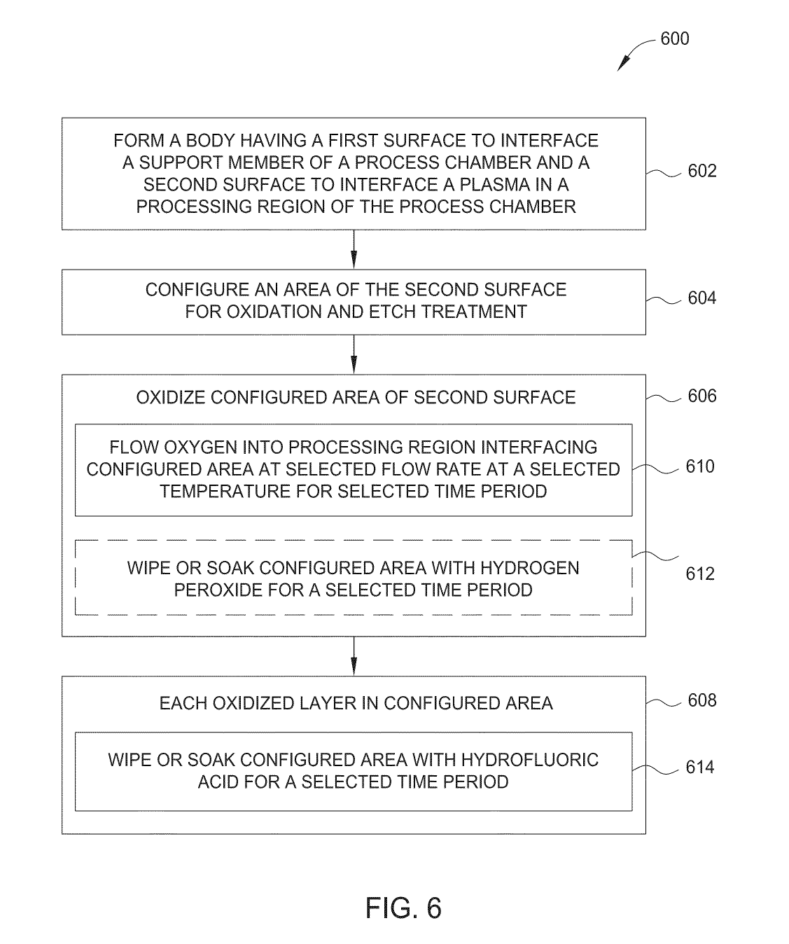

FIG. 6 is a flow diagram depicting a method 600 of fabricating a component for use in a semiconductor process chamber according to another embodiment. The method 600 is completed prior to initial first use of the component in the process chamber 100. The method 600 begins at step 602, where a body is formed having a first surface to interface a support member of the process chamber and a second surface to interface a plasma in a processing region of the process chamber. At step 604, an area of the second surface is configured for oxidation and etch treatment. For example, one or more masks can be used to expose the area of the second surface for treatment, while shielding other areas of the component from the treatment. At step 606, the second surface is oxidized within the configured area to form an oxidized layer. At step 608, the oxidized layer is etched to provide a treated area.

In one embodiment, the oxidation step 606 includes a step 610, where oxygen is flowed into a processing region of a chamber that interfaces the configured area at a selected flow rate at a selected temperature for a selected time period. In an embodiment, the selected flow rate is between 50 and 1000 standard cubic centimeters per minute (SCCM), the temperature is between 1000 and 1300 degrees Celsius (° C.), and the selected time period is between 1 and 3 hours. Such flow rate, temperature, and time parameters can be used when the treated area 210 includes quartz, silicon carbide, or a combination of such materials. In another embodiment, the oxidation step 606 includes a step 612, where the configured area is wiped or soaked with hydrogen peroxide (H₂O₂) for a selected time period. In an embodiment, the selected time period is between 30 and 120 minutes. Such a time period can be used when the treated area 210 includes quartz, silicon carbide, or a combination of such materials.

In one embodiment, etch step 608 includes a step 614, where the configured area is wiped or soaked with hydrofluoric acid (HF) for a selected time period. In an embodiment, the selected time period is between 30 and 120 minutes. Such a time period can be used when the treated area 210 includes quartz, silicon carbide, or a combination of such materials. After completion of the method 600, the component is ready for cleaning and subsequent use in the process chamber 100.

FIG. 5C shows a SEM image 506 of an oxidized and etch treated surface of a silicon carbide component. As shown, the treated surface includes less jagged, fractured, and/or sharp peaks than the untreated surface shown in FIG. 5A (e.g., generally flatter peaks). Components comprising other materials, such as quartz, exhibit similar surface morphology after thermal sublimation treatment.

A surface treatment for components having plasma facing surfaces in a semiconductor process chamber has been described. During manufacture, machined surfaces of a component, such as a showerhead, liner, shield (e.g., ring), and the like exhibit a morphology having jagged, fractured, and/or sharp peaks. If left untreated, the plasma facing surface can emit particles that can contaminate the semiconductor wafer being processed. In various examples described above, an area of the plasma facing surface of the component is treated to enhance surface morphology to reduce particle emission in the presence of processing gas, such as a plasma. The treated area of the plasma facing surface exhibits a morphology having less jagged, fractured, and/or sharp peaks (generally flatter peaks) than the post-machined, untreated surface.

While the foregoing is directed to embodiments of the present invention, other and further embodiments of the disclosure may be devised without departing from the basic scope thereof, and the scope thereof is determined by the claims that follow.

What is claimed is:

1. A component for use in a semiconductor process chamber, comprising:
a body having machined surfaces, including:
a first surface configured to interface with a support member of the semiconductor process chamber;
a second surface configured to face a processing region of the semiconductor process chamber; and
a treated area of the second surface having relatively flatter peaks than an untreated area of the machined surfaces and having an average roughness between 1 and 30 micro-inches.

2. The component of claim 1, wherein the treated area of the second surface includes an oxidized and etched area of the second surface.

3. The component of claim 1, wherein the treated area of the second surface includes a layer remaining after thermal sublimation of another layer of the second surface.

4. The component of claim 1, wherein the body comprises at least a portion of a shield, a shower head, or a liner disposed in the semiconductor process chamber.

5. The component of claim 1, wherein the support member comprises a substrate support, and the body comprises a ring assembly.

6. The component of claim 1, wherein the body comprises silicon carbide.

7. The component of claim 1, wherein the body comprises a dielectric material, and the second surface comprises a silicon carbide coating on the dielectric material.

8. A method of fabricating a component for use in a semiconductor process chamber, comprising:
forming a body having machined surfaces, the machined surfaces including a first surface to interface a support member of the semiconductor process chamber and a second surface to interface a processing region of the semiconductor process chamber;
configuring an area of the second surface for thermal sublimation treatment; and
exposing the area of the second surface to a temperature above a sublimation temperature of a material of the second surface to form a treated area of the second surface having relatively flatter peaks than prior the thermal sublimation treatment.

9. The method of claim 8, wherein the step of exposing comprises:
maintaining the area of the second surface at temperature between 1600 and 2300 degrees Celsius (° C.) for a time period.

10. The method of claim 9, wherein the step of exposing comprises:
maintaining the area of the second surface at a pressure between 10⁻³ and 10⁻⁷ standard atmosphere (atm) during the time period.

11. The method of claim 10, wherein the time period is between 2 and 10 hours.

12. The method of claim 8, wherein a layer of the second surface having a thickness between 20 and 50 micrometers (μm) is sublimated within the area during the step of exposing.

13. The method of claim 8, wherein the component comprises silicon carbide.

14. The method of claim 8, wherein the component comprises a dielectric material, and the second surface comprises a silicon carbide coating on the dielectric material.

15. A method of fabricating a component for use in a semiconductor process chamber, comprising:
forming a body having machined surfaces, the machined surfaces including a first surface to interface a support member of the semiconductor process chamber and a second surface to interface a processing region of the semiconductor process chamber;
configuring an area of the second surface for treatment;
oxidizing the second surface within the area to form an oxidized layer of the second surface; and
etching the oxidized layer to provide a treated area of the second surface having relative flatter peaks than prior the treatment.

16. The method of claim 15, wherein the step of oxidizing comprises:
flowing oxygen into a processing region interfacing the area of the second surface at a flow rate between 50-1000 standard cubic centimeters per minute (SCCM), at a temperature between 1000 and 1300 degrees Celsius (° C.), for a time period between 1 and 3 hours.

17. The method of claim 15, wherein the step of oxidizing comprises:
wiping or soaking the second surface within the area with hydrogen peroxide (H₂O₂) for a time period between 30 and 120 minutes.

18. The method of claim 15, wherein the step of etching comprises:
wiping or soaking the oxidized layer of the second surface with hydrofluoric acid (HF) for a time period between 30 and 120 minutes.

19. The method of claim 15, wherein the component comprises silicon carbide.

20. The method of claim 15, wherein the component comprises a dielectric material, and the surface comprises a silicon carbide coating on the dielectric material.
